(19) United States
(12) Patent Application Publication
(10) Pub. No.: US 2025/0204101 A1
(43) Pub. Date: Jun. 19, 2025

(54) CHIP TRANSFERRING AND BONDING DEVICE, CHIP BONDING DEVICE, AND CHIP TRANSFERRING AND BONDING METHOD

(71) Applicant: ASTI GLOBAL INC., TAIWAN, Taichung City (TW)

(72) Inventor: CHIEN-SHOU LIAO, Taichung City (TW)

(21) Appl. No.: 18/430,587

(22) Filed: Feb. 1, 2024

(30) Foreign Application Priority Data
Dec. 19, 2023 (TW) 112149376

(51) Int. Cl. H01L 33/48; H01L 25/075

(52) U.S. Cl. CPC H10H 20/8506; H01L 25/0753

(57) ABSTRACT

A chip transferring and bonding device, a chip bonding device and a chip transferring and bonding method are provided. The chip transferring and bonding device includes a signal control module, a chip carrying module, a chip transferring module and a laser light generation module. The chip transferring module is configured to transfer a plurality of chips to the circuit substrate. When the chips are transferred to the circuit substrate, the laser light generation module is configured to generate a laser beam, and the laser beam is focused at any position away from one of the chips to form a light focusing area and a heat radiation area away from the light focusing area. The soldering materials are allowed to be cured through a predetermined radiation temperature provided by the heat radiation area, thereby making each of the chips bonded on the circuit substrate through the soldering material.

### CROSS-REFERENCE TO RELATED PATENT APPLICATION

This application claims the benefit of priority to Taiwan Patent Application No. 112149376, filed on Dec. 19, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip transferring and bonding device, a chip bonding device, and a chip transferring and bonding method, and more particularly to a semiconductor chip transferring and bonding device, a semiconductor chip bonding device, and a semiconductor chip transferring and bonding method.

### BACKGROUND OF THE DISCLOSURE

In the related art, chips can be bonded to a circuit board by laser soldering. However, there is still room for improvement in the related art of laser soldering devices and laser soldering methods.

### SUMMARY OF THE DISCLOSURE

In response to the above-referenced technical inadequacy, the present disclosure provides a chip transferring and bonding device, a chip bonding device and a chip transferring and bonding method.

In order to solve the above-mentioned problems, one of the technical aspects adopted by the present disclosure is to provide a chip transferring and bonding device, which includes a signal control module, a chip carrying module, a chip transferring module and a laser light generation module. The chip carrying module is electrically connected to the signal control module. The chip transferring module is movably disposed above the chip carrying module and electrically connected to the signal control module. The laser light generation module is movably disposed above the chip carrying module and electrically connected to the signal control module. When the chip carrying module needs to be configured to carry a circuit substrate, the chip transferring module is allowed to be configured to transfer a plurality of chips to the circuit substrate through the signal control module, and each of the chips is allowed to be electrically connected to the circuit substrate through a plurality of soldering materials. When the chip transferring module needs to be configured to transfer the chips to the circuit substrate through the signal control module, the laser light generation module is allowed to be configured to generate a laser beam through the signal control module, and the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material.

In order to solve the above-mentioned problems, another one of the technical aspects adopted by the present disclosure is to provide a chip bonding device, which includes a signal control module, a chip carrying module and a laser light generation module. The chip carrying module is electrically connected to the signal control module, and the laser light generation module is movably disposed above the chip carrying module and electrically connected to the signal control module. When a plurality of chips need to be configured to be electrically connected to a circuit substrate through a plurality of soldering materials, the laser light generation module is allowed to be configured to generate a laser beam through the signal control module, and the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material.

In order to solve the above-mentioned problems, yet another one of the technical aspects adopted by the present disclosure is to provide a chip transferring and bonding method, which includes: carrying a circuit substrate through a chip carrying module; transferring a plurality of chips to the circuit substrate through a chip transferring module, in which each of the chips is allowed to be configured to be electrically connected to the circuit substrate through a plurality of soldering materials; and generating a laser beam through a laser light generation module, in which the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material. The chip carrying module, the chip transferring module and the laser light generation module are configured to be electrically connected to a signal control module.

Therefore, in the chip transferring and bonding device and the chip bonding device provided by the present disclosure, by virtue of “the laser light generation module being allowed to be configured to generate a laser beam through the signal control module,” “the laser beam being allowed to be focused at any position away from one of the chips to form a light focusing area and a heat radiation area away from the light focusing area” and “the soldering materials being allowed to be cured through a predetermined radiation temperature that is provided by the heat radiation area of the laser beam,” each of the chips can be allowed to be bonded on the circuit substrate through the soldering material.

Furthermore, in the chip transferring and bonding method provided by the present disclosure, by virtue of “generating a laser beam through a laser light generation module,” “the laser beam being allowed to be focused at any position away from one of the chips to form a light focusing area and a heat radiation area away from the light focusing area” and “the soldering materials being allowed to be cured through a predetermined radiation temperature that is provided by the heat radiation area of the laser beam,” each of the chips can be allowed to be bonded on the circuit substrate through the soldering material.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a chip transferring and bonding method provided by the present disclosure;

FIG. 2 is a functional block diagram of a chip transferring and bonding device provided by the present disclosure;

FIG. 3 is a schematic view of a chip carrying module configured for carrying a circuit substrate and a chip transferring module configured for transferring a plurality of chips according to the present disclosure;

FIG. 4 is a schematic view of the chip transferring and bonding device using a laser light generation module to generate a laser beam focused on one of the chips according to a first embodiment of the present disclosure;

FIG. 5 is a schematic view of the chip transferring and bonding device using the laser light generation module to generate a laser beam focused below one of the chips according to the first embodiment of the present disclosure;

FIG. 6 is a schematic view of the chip transferring module configured for removing a transparent substrate according to the present disclosure;

FIG. 7 is a schematic view of the chip transferring and bonding device using the laser light generation module to generate a laser beam focused on one of the chips according to a second embodiment of the present disclosure;

FIG. 8 is a schematic view of the chip transferring and bonding device using the laser light generation module to generate a laser beam focused below one of the chips according to the second embodiment of the present disclosure;

FIG. 9 is a schematic view of the chip transferring and bonding device using the laser light generation module to generate a laser beam focused on one of the chips according to a third embodiment of the present disclosure; and

FIG. 10 is a schematic view of the chip transferring and bonding device using the laser light generation module to generate a laser beam focused below one of the chips according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

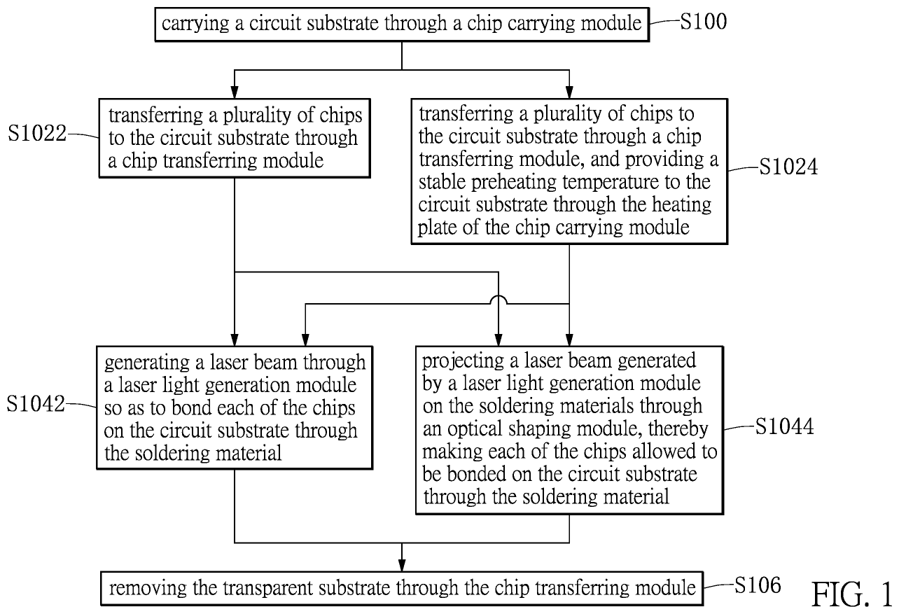

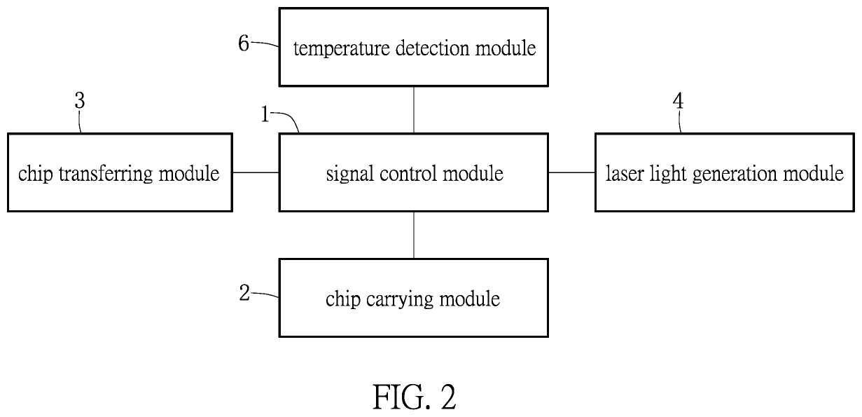

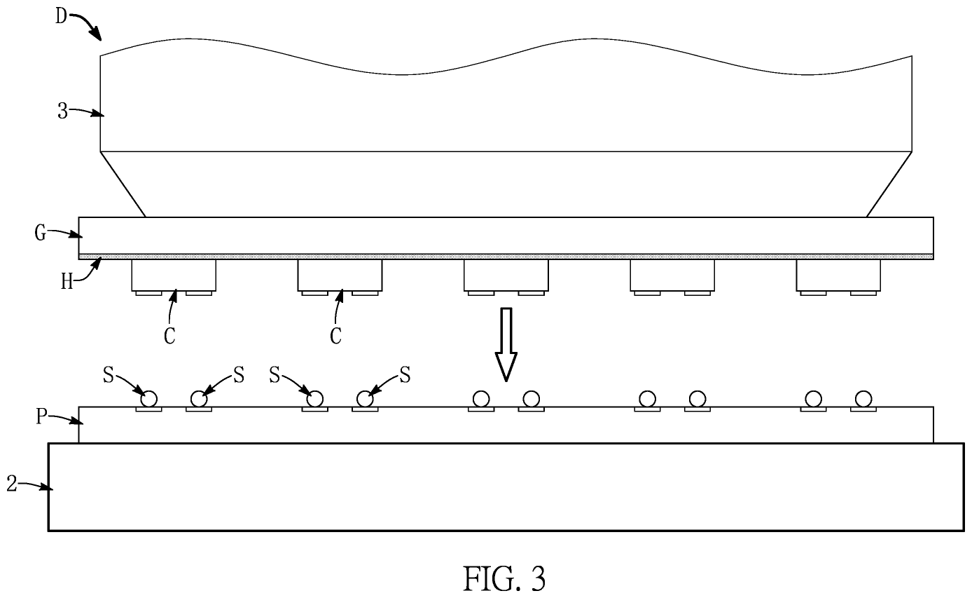

Referring to FIG. 1 to FIG. 6, a first embodiment of the present disclosure provides a chip transferring and bonding method, which may include the following steps: firstly, referring to FIG. 1, FIG. 2 and FIG. 3, carrying a circuit substrate P (such as any carrier substrate having a circuit layout) through a chip carrying module 2 (such as a movable clamp, a movable vacuum chuck or any kind of movable stage) (step S100); next, referring to FIG. 1, FIG. 2,

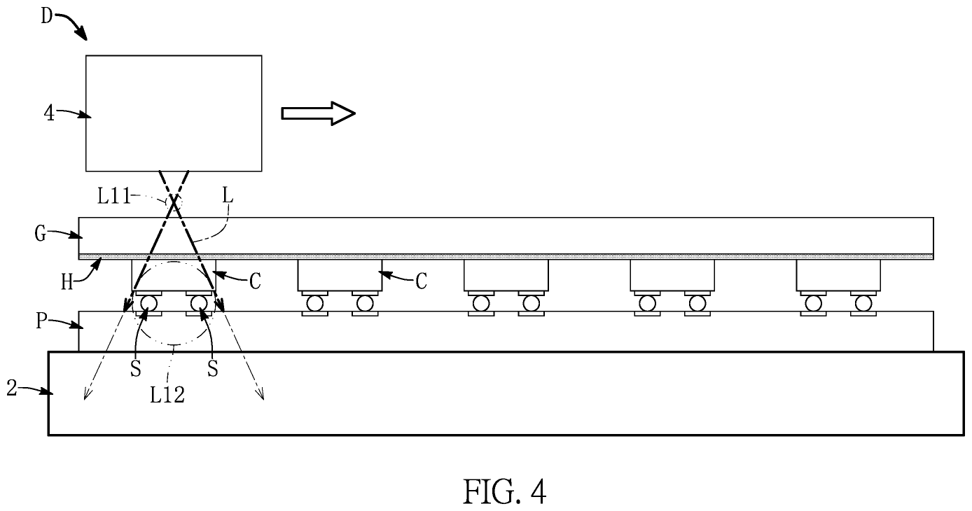

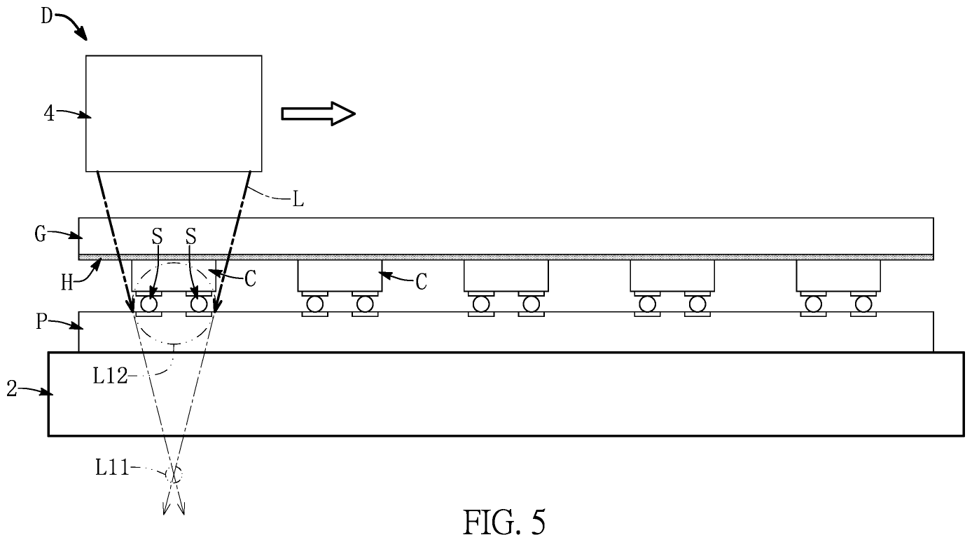

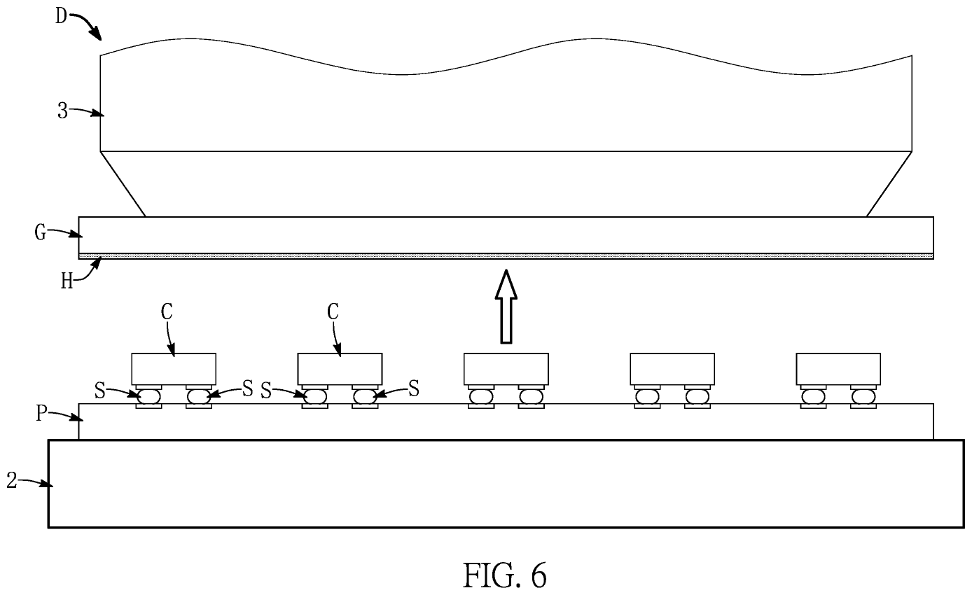

FIG. 3 and FIG. 4, transferring a plurality of chips C (such as a plurality of light-emitting diode chips, a plurality of integrated circuit chips, or any kind of chips that are pre-adhered to a transparent substrate G such as glass through an adhesive layer H, or one or more chips C can also be sucked through a vacuum nozzle in advance) to the circuit substrate P through a chip transferring module 3 (such as a movable gripper, a movable vacuum nozzle or any kind of chip transferring structure), in which each of the chips C can be allowed to be configured to be electrically connected to the circuit substrate P through a plurality of soldering materials S (such as a plurality of solder balls or any kind of solder bodies placed on the circuit substrate P or the chips C in advance) (step S1022); then, referring to FIG. 1, FIG. 2 and FIG. 4 (or FIG. 5), generating a laser beam L (or a laser light source) through a laser light generation module 4 (such as a laser focusing module having a fixed focusing processing head or any kind of laser light providing module), thereby making each of the chips C allowed to be bonded on the circuit substrate P through the soldering material S (step S1042); afterward, referring to FIG. 1, FIG. 2 and FIG. 6, removing the transparent substrate G through the chip transferring module 3 (step S106). More particularly, after the step S106, the chip transferring and bonding method can further include a cleaning step of removing residues that may remain on the outer surface of chip C (such as a part of the residual material of the adhesive layer H). In addition, referring to FIG. 4 or FIG. 5, in the step S1042, the laser beam L can be allowed to be focused at any position (for example, as shown in FIG. 4, the laser beam L can be allowed to be focused above one of the chips C, or as shown in FIG. 5, the laser beam L is allowed to be focused below one of the chips C) away from one of the chips C to form a light focusing area L11 (or a light focusing region) and a heat radiation area L12 (or a heat radiation area L12 allowed to cover at least one chip C) away from the light focusing area L11, and the soldering materials S can be allowed to be cured through a predetermined radiation temperature (or a predetermined soldering temperature) that is provided by the heat radiation area L12 of the laser beam L. However, the aforementioned details are disclosed for exemplary purposes only, and are not meant to limit the scope of the present disclosure.

It should be noted that, referring to FIG. 2, FIG. 3 and FIG. 4 (or FIG. 5), the first embodiment of the present disclosure further provides a chip transferring and bonding device D that can be configured to be applied to the chip transferring and bonding method provided by the first embodiment of the present disclosure. More particularly, the chip transferring and bonding device D includes the signal control module 1, the chip carrying module 2, the chip transferring module 3 and the laser light generation module 4, and the signal control module 1, the chip carrying module 2 and the laser light generation module 4 can cooperate with each other to define a chip bonding device. In addition, the chip carrying module 2, the chip transferring module 3 and the laser light generation module 4 are configured to be electrically connected to a signal control module 1, the chip transferring module 3 is movably disposed above the chip carrying module 2, and the laser light generation module 4 is movably disposed above the chip carrying module 2.

For example, referring to FIG. 3 and FIG. 4, when the chip carrying module 2 needs to be configured to carry a circuit substrate P, the chip transferring module 3 can be allowed to be configured to transfer a plurality of chips C to the circuit substrate P through the signal control module 1, and each of the chips C can be allowed to be electrically connected to the circuit substrate P through a plurality of soldering materials S. In addition, referring to FIG. 4 or FIG. 5, when the chip transferring module 3 needs to be configured to transfer the chips C to the circuit substrate P through the signal control module 1, the laser light generation module 4 can be allowed to be configured to generate a laser beam L through the signal control module 1, the laser beam L can be allowed to be focused at any position away from one of the chips C to form a light focusing area L11 (as shown in FIG. 4, the laser beam L is allowed to be focused above one of the chips C to form a light focusing area L11; as shown in FIG. 5, the laser beam L is allowed to be focused below one of the chips C to form a light focusing area L11; or any position surrounding one of the chips C) and a heat radiation area L12 away from the light focusing area L11, and the soldering materials S can be allowed to be cured (such as melting and then solidifying) through a predetermined radiation temperature that is provided by the heat radiation area L12 of the laser beam L, thereby making each of the chips C (such as, mini LED chips or micro LED chips) allowed to be bonded on the circuit substrate P through the soldering material S. However, the aforementioned details are disclosed for exemplary purposes only, and are not meant to limit the scope of the present disclosure.

Therefore, as shown in FIG. 4, when the laser light generation module 4 needs to be configured to generate the laser beam L through the signal control module 1, the light focusing area L11 that is formed by focusing the laser beam L above the chip can be away from the chips C by a predetermined distance, thereby preventing the chips C from being damaged by a high temperature of the light focusing area L11 generated by the laser beam L. In addition, as shown in FIG. 5, when the laser light generation module 4 needs to be configured to generate the laser beam L through the signal control module 1, the light focusing area L11 (i.e., a virtual light focusing area) that is formed by focusing the laser beam L below the chip can be away from the chips C by a predetermined distance, thereby preventing the chips C from being damaged by a high temperature of the light focusing area L11 generated by the laser beam L.

### Second Embodiment

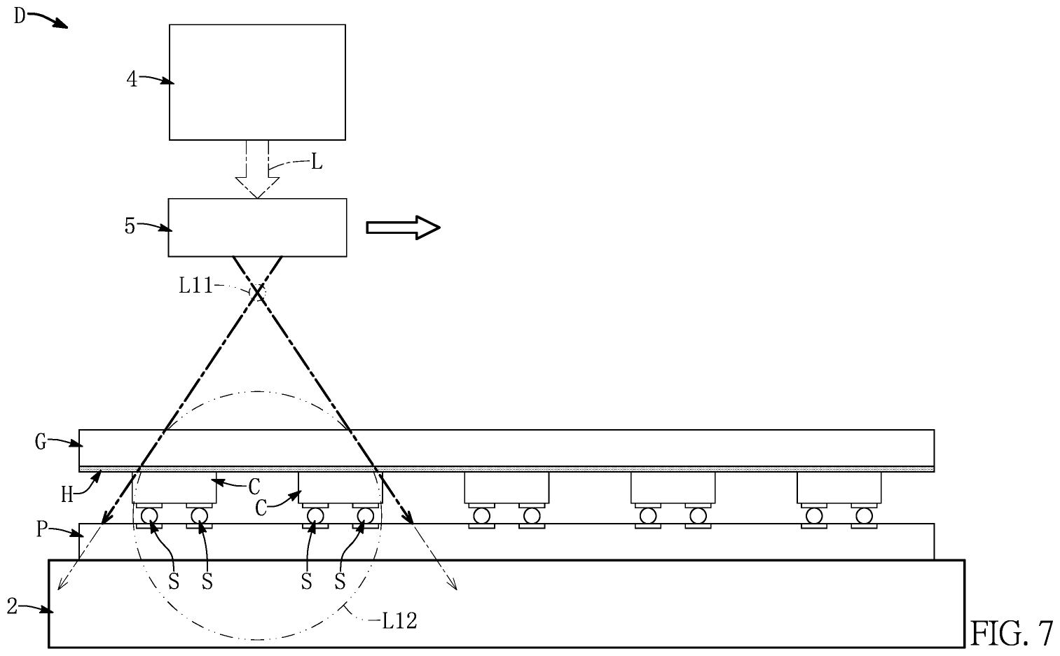

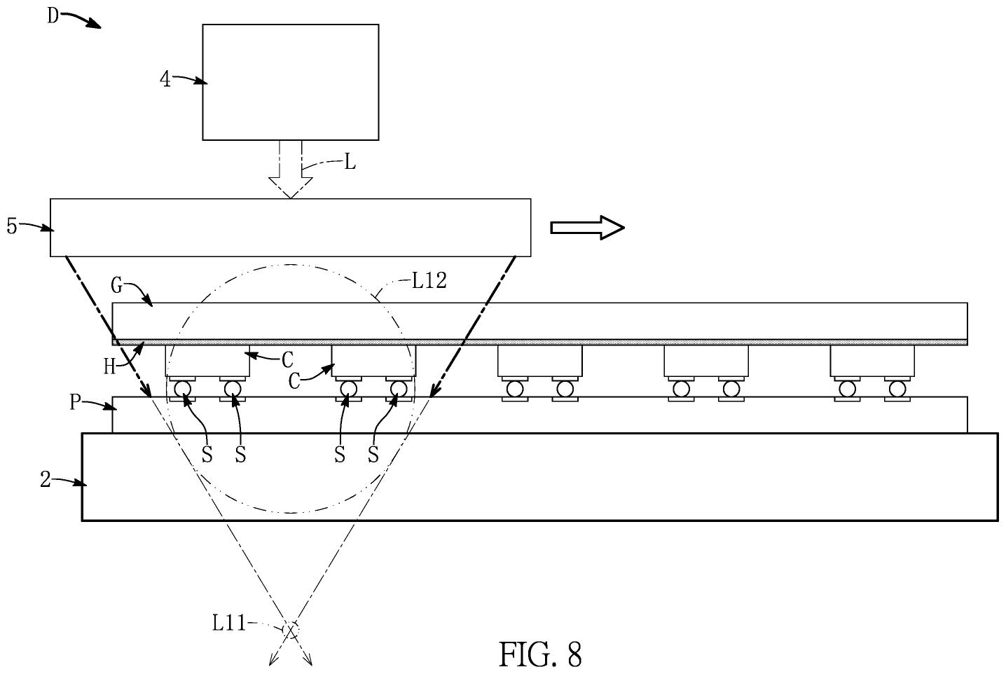

Referring to FIG. 1, FIG. 2, FIG. 7 and FIG. 8, a second embodiment of the present disclosure provides a chip transferring and bonding method and a chip transferring and bonding device D. Comparing FIG. 7 with FIG. 4, or comparing FIG. 8 with FIG. 5, the main difference between the second embodiment and the first embodiment is as follows: in the second embodiment, when the chip transferring module 3 needs to be configured to transfer the chips C to the circuit substrate P through the signal control module 1 (i.e., the step S1022), the laser beam L generated by the laser light generation module 4 can be allowed to generate a linear light spot area (or a strip-shaped small-area laser spot) or a rectangular light spot area (or a rectangular large-area laser spot) that is projected on the soldering materials S (i.e., the solder materials S that are contacted by at least two chips C) through an optical shaping module 5 (such as including a plurality of microlens arrays), thereby increasing the soldering efficiency of the chip transferring and bonding device D. That is to say, after the step S1022 of transferring the chips C to the circuit substrate P, the chip transferring and bonding method provided by the second embodiment of the present disclosure may further include: generating a laser beam L (or a laser light source) through a laser light generation module 4 (such as a laser focusing module having a fixed focusing processing head or any kind of laser light providing module), in which the laser beam L generated by the laser light generation module 4 can be allowed to be projected on the soldering materials S through an optical shaping module 5, thereby making each of the chips C allowed to be bonded on the circuit substrate P through the soldering material S (step S1044).

Therefore, as shown in FIG. 7, when the laser light generation module 4 needs to be configured to generate the laser beam L through the signal control module 1, the light focusing area L11 that is formed by focusing the laser beam L above the chip through an optical shaping module 5 can be away from the chips C by a predetermined distance, thereby preventing the chips C from being damaged by a high temperature of the light focusing area L11 generated by the laser beam L. In addition, as shown in FIG. 8, when the laser light generation module 4 needs to be configured to generate the laser beam L through the signal control module 1, the light focusing area L11 (i.e., a virtual light focusing area) that is formed by focusing the laser beam L below the chip through another optical shaping module 5 can be away from the chips C by a predetermined distance, thereby preventing the chips C from being damaged by a high temperature of the light focusing area L11 generated by the laser beam L.

### Third Embodiment

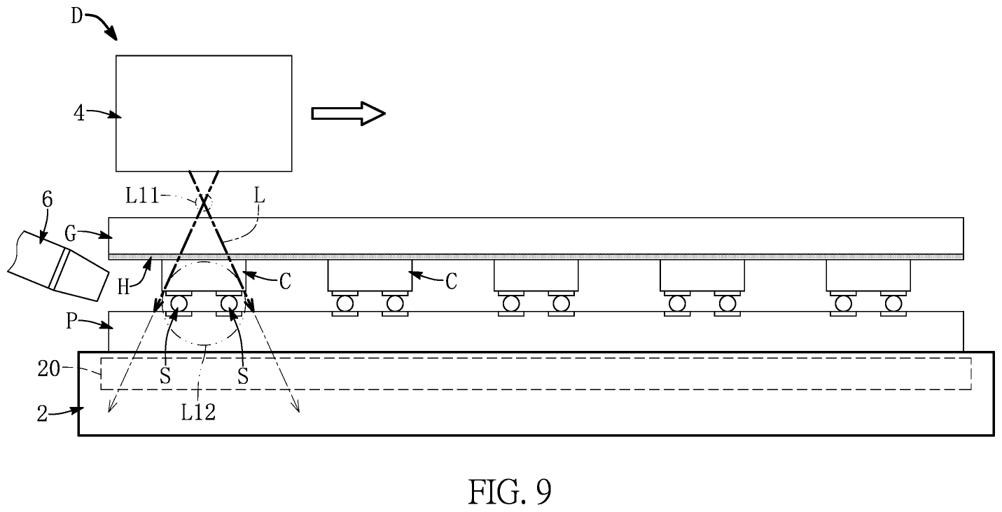

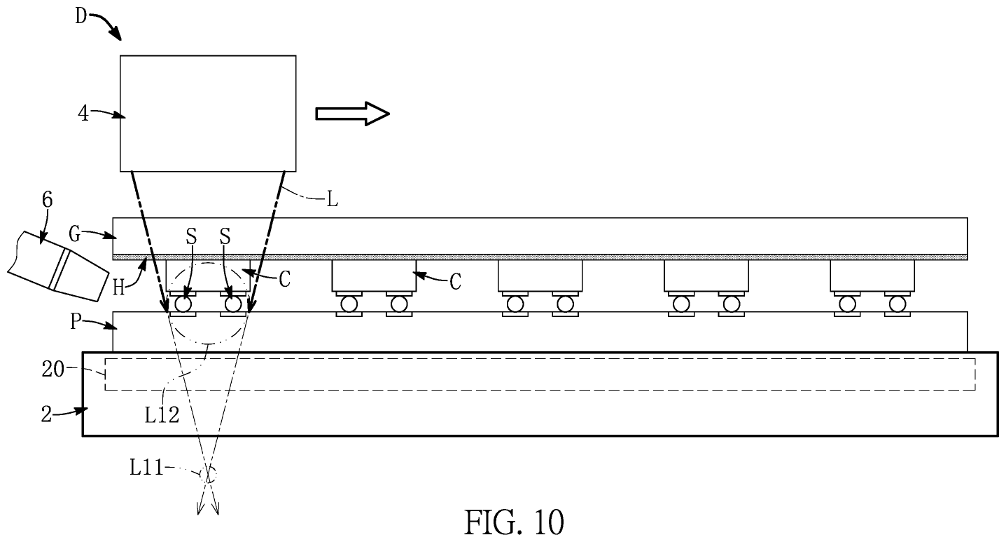

Referring to FIG. 1, FIG. 2, FIG. 9 and FIG. 10, a third embodiment of the present disclosure provides a chip transferring and bonding method and a chip transferring and bonding device D. Comparing FIG. 9 with FIG. 4, or comparing FIG. 10 with FIG. 5, the main difference between the third embodiment and the first embodiment is as follows: in the third embodiment, the chip carrying module 2 has a heating plate 20 (or a heater) disposed inside or outside, and the heating plate 20 can be configured to adjust a temperature of the chip carrying module 2. Therefore, when the chip carrying module 2 needs to be configured to carry the circuit substrate P through the signal control module 1 (i.e., the step S1022), the heating plate 20 of the chip carrying module 2 can be allowed to be configured to provide a stable preheating temperature to the circuit substrate P through the signal control module 1, and the stable preheating temperature is lower than the predetermined radiation temperature (or a predetermined soldering temperature) to prevent the soldering materials S from being solidified or cured due to the stable preheating temperature. That is to say, after the step S100 of carrying the circuit substrate P through the chip carrying module 2, the chip transferring and bonding method provided by the third embodiment of the present disclosure may further include: transferring a plurality of chips C (such as a plurality of light-emitting diode chips, a plurality of integrated circuit chips, or any kind of chips that are pre-adhered to a transparent substrate G such as glass through an adhesive layer H, or one or more chips C can also be sucked through a vacuum nozzle in advance) to the circuit substrate P through a chip transferring module 3 (such as a movable gripper, a movable vacuum nozzle or any kind of chip transferring structure), and providing a stable preheating temperature (or a continuously fixed preheating temperature) to the circuit substrate P through the heating plate 20 of the chip carrying module 2 (step S1024), thereby preventing the soldering strength from being reduced due to residual stress (residual stress will make chip C easily affected by external forces and detached from the circuit substrate

P) generated by the soldering materials S during the soldering and cooling processes of the soldering materials S.

More particularly, comparing FIG. 9 with FIG. 4, or comparing FIG. 10 with FIG. 5, the main difference between the third embodiment and the first embodiment is as follows: in the third embodiment, the chip transferring and bonding device D further includes a temperature detection module 6 that can be movably adjacent to the chip carrying module 2 and electrically connected to the signal control module 1. That is to say, the chip transferring and bonding method provided by the third embodiment of the present disclosure may further include: detecting a temperature of the laser beam L through a temperature detection module 6. For example, when the laser light generation module 4 needs to be configured to generate the laser beam L through the signal control module 1, the temperature detection module 6 can be allowed to be configured to detect the predetermined radiation temperature that is provided by the heat radiation area L12 of the laser beam L through the signal control module 1. Moreover, when the predetermined radiation temperature that is provided by the heat radiation area L12 of the laser beam L and detected by the temperature detection module 6 is lower than a predetermined soldering temperature of the soldering material S, the laser light generation module 4 can be allowed to increase a power value of the laser beam L through the signal control module 1, thereby increasing a bonding yield rate of each of the chips C that is bonded on the circuit substrate P. In addition, when the predetermined radiation temperature that is provided by the heat radiation area L12 of the laser beam L and detected by the temperature detection module 6 is higher than the predetermined soldering temperature of the soldering material S, the laser light generation module 4 can be allowed to reduce a power value of the laser beam L through the signal control module 1, thereby increasing a bonding yield rate of each of the chips C that is bonded on the circuit substrate P. However, the aforementioned details are disclosed for exemplary purposes only, and are not meant to limit the scope of the present disclosure.

Therefore, as shown in FIG. 9, when the laser light generation module 4 needs to be configured to generate the laser beam L through the signal control module 1, the light focusing area L11 that is formed by focusing the laser beam L above the chip can be away from the chips C by a predetermined distance, thereby preventing the chips C from being damaged by a high temperature of the light focusing area L11 generated by the laser beam L. In addition, as shown in FIG. 10, when the laser light generation module 4 needs to be configured to generate the laser beam L through the signal control module 1, the light focusing area L11 (i.e., a virtual light focusing area) that is formed by focusing the laser beam L below the chip can be away from the chips C by a predetermined distance, thereby preventing the chips C from being damaged by a high temperature of the light focusing area L11 generated by the laser beam L. [Beneficial Effects of the Embodiments]

In conclusion, in the chip transferring and bonding device D and the chip bonding device provided by the present disclosure, by virtue of “the laser light generation module 4 being allowed to be configured to generate a laser beam L through the signal control module 1,” “the laser beam L being allowed to be focused at any position away from one of the chips C to form a light focusing area L11 and a heat radiation area L12 away from the light focusing area L11” and “the soldering materials S being allowed to be cured through a predetermined radiation temperature that is provided by the heat radiation area L12 of the laser beam L,” each of the chips C can be allowed to be bonded on the circuit substrate P through the soldering material S.

Furthermore, in the chip transferring and bonding method provided by the present disclosure, by virtue of “generating a laser beam L through a laser light generation module 4,” “the laser beam L being allowed to be focused at any position away from one of the chips C to form a light focusing area L11 and a heat radiation area L12 away from the light focusing area L11” and “the soldering materials S being allowed to be cured through a predetermined radiation temperature that is provided by the heat radiation area L12 of the laser beam L,” each of the chips C can be allowed to be bonded on the circuit substrate P through the soldering material S.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip transferring and bonding device, comprising:
a signal control module;
a chip carrying module electrically connected to the signal control module;
a chip transferring module movably disposed above the chip carrying module and electrically connected to the signal control module; and
a laser light generation module movably disposed above the chip carrying module and electrically connected to the signal control module;
wherein, when the chip carrying module needs to be configured to carry a circuit substrate, the chip transferring module is allowed to be configured to transfer a plurality of chips to the circuit substrate through the signal control module, and each of the chips is allowed to be electrically connected to the circuit substrate through a plurality of soldering materials;
wherein, when the chip transferring module needs to be configured to transfer the chips to the circuit substrate through the signal control module, the laser light generation module is allowed to be configured to generate a laser beam through the signal control module, and the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material.

2. The chip transferring and bonding device according to claim 1,
wherein the chip carrying module has a heating plate disposed inside or outside, and the heating plate is configured to adjust a temperature of the chip carrying module;
wherein, when the chip carrying module needs to be configured to carry the circuit substrate through the signal control module, the heating plate of the chip carrying module is allowed to be configured to provide a stable preheating temperature to the circuit substrate through the signal control module, and the stable preheating temperature is lower than the predetermined radiation temperature to prevent the soldering materials from being solidified due to the stable preheating temperature;
wherein, when the chip transferring module needs to be configured to transfer the chips to the circuit substrate through the signal control module, the laser beam generated by the laser light generation module is allowed to generate a linear light spot area or a rectangular light spot area that is projected on the soldering materials through an optical shaping module;
wherein, when the laser light generation module needs to be configured to generate the laser beam through the signal control module, the light focusing area that is formed by focusing the laser beam above or below the chip is away from the chips, thereby preventing the chips from being damaged by a high temperature of the light focusing area generated by the laser beam.

3. The chip transferring and bonding device according to claim 1, wherein the chip transferring and bonding device further includes a temperature detection module movably adjacent to the chip carrying module and electrically connected to the signal control module;
wherein, when the laser light generation module needs to be configured to generate the laser beam through the signal control module, the temperature detection module is allowed to be configured to detect the predetermined radiation temperature that is provided by the heat radiation area of the laser beam through the signal control module;
wherein, when the predetermined radiation temperature that is provided by the heat radiation area of the laser beam and detected by the temperature detection module is lower than a predetermined soldering temperature of the soldering material, the laser light generation module is allowed to increase a power value of the laser beam through the signal control module, thereby increasing a bonding yield rate of each of the chips bonded on the circuit substrate;
wherein, when the predetermined radiation temperature that is provided by the heat radiation area of the laser beam and detected by the temperature detection module is higher than the predetermined soldering temperature of the soldering material, the laser light generation module is allowed to reduce the power value of the laser beam through the signal control module, thereby increasing a bonding yield rate of each of the chips bonded on the circuit substrate;
wherein, each of the chips is a light-emitting diode chip or an integrated circuit chip.

4. A chip bonding device, comprising:
a signal control module;
a chip carrying module electrically connected to the signal control module; and
a laser light generation module movably disposed above the chip carrying module and electrically connected to the signal control module;
wherein, when a plurality of chips need to be configured to be electrically connected to a circuit substrate through a plurality of soldering materials, the laser light generation module is allowed to be configured to generate a laser beam through the signal control module, and the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material.

5. The chip bonding device according to claim 4,
wherein the chip carrying module has a heating plate disposed inside or outside, and the heating plate is configured to adjust a temperature of the chip carrying module;
wherein, when the chip carrying module needs to be configured to carry the circuit substrate through the signal control module, the heating plate of the chip carrying module is allowed to be configured to provide a stable preheating temperature to the circuit substrate through the signal control module, and the stable preheating temperature is lower than the predetermined radiation temperature to prevent the soldering materials from being solidified due to the stable preheating temperature;
wherein, when the chips need to be configured to be electrically connected to the circuit substrate through the soldering materials, the laser beam generated by the laser light generation module is allowed to generate a linear light spot area or a rectangular light spot area that is projected on the soldering materials through an optical shaping module;
wherein, when the laser light generation module needs to be configured to generate the laser beam through the signal control module, the light focusing area that is formed by focusing the laser beam above or below the chip is away from the chips, thereby preventing the chips from being damaged by a high temperature of the light focusing area generated by the laser beam.

6. The chip bonding device according to claim 4,
wherein the chip bonding device further includes a temperature detection module movably adjacent to the chip carrying module and electrically connected to the signal control module;
wherein, when the laser light generation module needs to be configured to generate the laser beam through the signal control module, the temperature detection module is allowed to be configured to detect the predetermined radiation temperature that is provided by the heat radiation area of the laser beam through the signal control module;
wherein, when the predetermined radiation temperature that is provided by the heat radiation area of the laser beam and detected by the temperature detection module is lower than a predetermined soldering temperature of the soldering material, the laser light generation module is allowed to increase a power value of the laser beam through the signal control module, thereby increasing a bonding yield rate of each of the chips bonded on the circuit substrate;
wherein, when the predetermined radiation temperature that is provided by the heat radiation area of the laser beam and detected by the temperature detection module is higher than the predetermined soldering temperature of the soldering material, the laser light generation module is allowed to reduce the power value of the laser beam through the signal control module, thereby increasing a bonding yield rate of each of the chips bonded on the circuit substrate;
wherein, each of the chips is a light-emitting diode chip or an integrated circuit chip.

7. A chip transferring and bonding method, comprising:
carrying a circuit substrate through a chip carrying module;
transferring a plurality of chips to the circuit substrate through a chip transferring module, wherein each of the chips is allowed to be configured to be electrically connected to the circuit substrate through a plurality of soldering materials; and
generating a laser beam through a laser light generation module, wherein the laser beam is allowed to be focused at any position away from one of the chips to form a light focusing area and a heat radiation area away from the light focusing area, and the soldering materials are allowed to be cured through a predetermined radiation temperature that is provided by the heat radiation area of the laser beam, thereby making each of the chips allowed to be bonded on the circuit substrate through the soldering material;
wherein the chip carrying module, the chip transferring module and the laser light generation module are configured to be electrically connected to a signal control module.

8. A chip transferring and bonding device configured to be applied to the chip transferring and bonding method as claimed in claim 7, characterized in that the chip transferring and bonding device includes the signal control module, the chip carrying module, the chip transferring module and the laser light generation module, the chip transferring module is movably disposed above the chip carrying module, and the laser light generation module is movably disposed above the chip carrying module.

9. The chip transferring and bonding method according to claim 7,
wherein the chip carrying module has a heating plate disposed inside or outside, and the heating plate is configured to adjust a temperature of the chip carrying module;
wherein, when the chip carrying module needs to be configured to carry the circuit substrate through the signal control module, the heating plate of the chip carrying module is allowed to be configured to provide a stable preheating temperature to the circuit substrate through the signal control module, and the stable preheating temperature is lower than the predetermined radiation temperature to prevent the soldering materials from being solidified due to the stable preheating temperature;
wherein, when the chip transferring module needs to be configured to transfer the chips to the circuit substrate through the signal control module, the laser beam generated by the laser light generation module is allowed to generate a linear light spot area or a rectangular light spot area that is projected on the soldering materials through an optical shaping module;
wherein, when the laser light generation module needs to be configured to generate the laser beam through the signal control module, the light focusing area that is formed by focusing the laser beam above or below the chip is away from the chips, thereby preventing the chips from being damaged by a high temperature of the light focusing area generated by the laser beam.

10. The chip transferring and bonding method according to claim 7,
wherein the chip transferring and bonding method further comprising: detecting a temperature of the laser beam through a temperature detection module;
wherein the temperature detection module is configured to be movably adjacent to the chip carrying module and electrically connected to the signal control module;
wherein, when the laser light generation module needs to be configured to generate the laser beam through the signal control module, the temperature detection module is allowed to be configured to detect the predetermined radiation temperature that is provided by the heat radiation area of the laser beam through the signal control module;
wherein, when the predetermined radiation temperature that is provided by the heat radiation area of the laser beam and detected by the temperature detection module is lower than a predetermined soldering temperature of the soldering material, the laser light generation module is allowed to increase a power value of the laser beam through the signal control module, thereby increasing a bonding yield rate of each of the chips bonded on the circuit substrate;
wherein, when the predetermined radiation temperature that is provided by the heat radiation area of the laser beam and detected by the temperature detection module is higher than the predetermined soldering temperature of the soldering material, the laser light generation module is allowed to reduce the power value of the laser beam through the signal control module, thereby increasing a bonding yield rate of each of the chips bonded on the circuit substrate;
wherein, each of the chips is a light-emitting diode chip or an integrated circuit chip.
